(19) United States
(12) Patent Application Publication
(10) Pub. No.: US 2023/0067301 A1
(43) Pub. Date: Mar. 2, 2023

(54) MASK AND MASK MANUFACTURING METHOD

(71) Applicant: DARWIN PRECISIONS CORPORATION, Hsinchu County (TW)

(72) Inventor: JEN SHUN LIN, Hsinchu County (TW)

(21) Appl. No.: 17/564,254

(22) Filed: Dec. 29, 2021

(30) Foreign Application Priority Data
Aug. 25, 2021 (TW) 110131396

(51) Int. Cl. C23C 14/24; C23C 14/04

(52) U.S. Cl. CPC C23C 14/24; C23C 14/04

(57) ABSTRACT

A mask manufacturing method includes the steps of: providing a substrate, wherein the substrate has a surface; forming a photoresist pattern on the substrate and covering a first part of the surface of the substrate with the photoresist pattern; providing a metal frame, wherein the metal frame has an inner wall enclosing a within-frame zone, and an area of the within-frame zone is smaller than an area of the surface of the substrate; assembling the metal frame and the substrate, so as to connect the inner wall with the surface and expose the photoresist pattern to the within-frame zone; and performing metal deposition in the within-frame zone and forming a deposited metal layer on the surface. The invention further provides a mask manufactured by the aforementioned mask manufacturing method.

### FIELD OF THE INVENTION

The present invention relates to a mask and a mask manufacturing method, and more particularly to an integrated metal mask and its manufacturing method.

### BACKGROUND OF THE INVENTION

The advancement of mobile technology and the miniaturization and weight reduction of mobile devices have brought new challenges to the forming and manufacturing of electronic components. Taking passive components as an example, their manufacturing relies on processes such as sputtering, evaporation, and printing, and the mask used in these processes is composed of a frame and a metal film fixed on the frame. In general, the metal film is provided by the yellow light process and etching and has a pattern of openings. Because the metal film is flexible, it is necessary to stretch the metal film through tension before being bonded to the frame. However, the tension stretching may cause the deformation or offset of the opening pattern. Specifically, the finer the opening pattern or the finer the size, the greater the deviation caused by the tension stretching, which causes the tolerance of the electronic component to exceed an appropriate range. In addition, processes such as etching also increase the chance of distortion of the opening pattern.

### SUMMARY OF THE INVENTION

The present invention provides a mask manufacturing method, which is helpful for forming a fine mask pattern to realize the manufacture of small or precise components.

The mask manufacturing method provided by the present invention includes the steps of: providing a substrate, wherein the substrate has a surface; forming a photoresist pattern on the substrate and covering a first part of the surface of the substrate with the photoresist pattern; providing a metal frame, wherein the metal frame has an inner wall enclosing a within-frame zone, and an area of the within-frame zone is smaller than an area of the surface of the substrate; assembling the metal frame and the substrate, so as to connect the inner wall with the surface and expose the photoresist pattern to the within-frame zone; and performing metal deposition in the within-frame zone and forming a deposited metal layer on the surface.

In an embodiment of the invention, the step of forming the photoresist pattern on the substrate further includes steps of: coating a photoresist on the surface of the substrate; exposing the photoresist by a photomask; and developing.

In an embodiment of the invention, the step of forming the photoresist pattern on the substrate further includes a step of: forming a second part on the surface, wherein the second part is exposed to the surface.

In an embodiment of the invention, the metal frame further has a bottom, and the step of assembling the metal frame and the substrate further includes a step of: abutting the bottom of the metal frame against the surface of the substrate.

In an embodiment of the invention, the step of assembling the metal frame and the substrate further includes a step of: using equipment to fix the metal frame on the substrate.

In an embodiment of the invention, the step of performing metal deposition in the within-frame zone further includes a step of: depositing at least one metal on the second part of the surface and the inner wall of the metal frame.

In an embodiment of the invention, the metal frame further has a top, and the step of performing metal deposition in the within-frame zone further includes a step of: depositing the at least one metal on the top.

In an embodiment of the invention, the step of performing metal deposition in the within-frame zone further includes a step of: integrally forming the deposited metal layer along the second part of the surface and the inner wall of the metal frame, and connecting the deposited metal layer to the metal frame.

In an embodiment of the invention, the aforementioned mask manufacturing method further includes steps of: removing the substrate; and removing the photoresist pattern and revealing a hollow pattern in the deposited metal layer, wherein the hollow pattern corresponds to the photoresist pattern.

In an embodiment of the invention, the hollow pattern has an aperture, and the aperture is less than 200 μm.

In an embodiment of the invention, the aperture is 3-7 μm, the aperture corresponds to a part of the photoresist pattern, and the part of the photoresist pattern has a width of 5 μm.

In an embodiment of the invention, the photoresist pattern has a first height on the surface, the deposited metal layer has a second height on the surface, and the second height is less than the first height.

The present invention further provides a mask manufactured by the aforementioned mask manufacturing method.

In an embodiment of the invention, the deposited metal layer has a thickness of 1-50 μm.

Because the present invention adopts the step of depositing metal to form the deposited metal layer, the etching and other procedures in the conventional method are omitted to simplify the process and avoid the superimposition of errors. Furthermore, because the present invention is free from the tension of the metal film, the deformation or deviation of the hole pattern can be avoided. Therefore, the invention can not only improve the fineness of the mask, but also reduce the tolerance range, thereby helping to realize the manufacture and development of small or precise components.

### BRIEF DESCRIPTION OF THE DRAWINGS

The present invention will become more readily apparent to those ordinarily skilled in the art after reviewing the following detailed description and accompanying drawings, in which:

FIG. 1 is a schematic flowchart of a mask manufacturing method according to an embodiment of the present invention;

FIG. 2 is a schematic top view of a substrate according to an embodiment of the present invention;

FIG. 3 is a schematic flowchart of a mask manufacturing method according to another embodiment of the present invention;

FIG. 4A is a schematic diagram illustrating the operation of the process shown in FIG. 3;

FIG. 4B is a schematic top view of a photomask according to an embodiment of the invention;

FIG. 5 is a schematic top view of a metal frame according to an embodiment of the present invention;

FIGS. 6A to 6B are schematic diagrams illustrating partial operations shown in FIG. 1;

FIGS. 7A to 7B are schematic diagrams illustrating partial operations shown in FIG. 1;

FIG. 8 is a schematic diagram illustrating partial operations shown in FIG. 1;

FIG. 9 is a schematic diagram illustrating partial operations shown in FIG. 1;

FIG. 10 is a schematic flowchart of a mask manufacturing method according to another embodiment of the present invention;

FIG. 11A is a schematic diagram illustrating an operation shown in FIG. 10; and

FIG. 11B is a schematic diagram illustrating another operation shown in FIG. 10.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

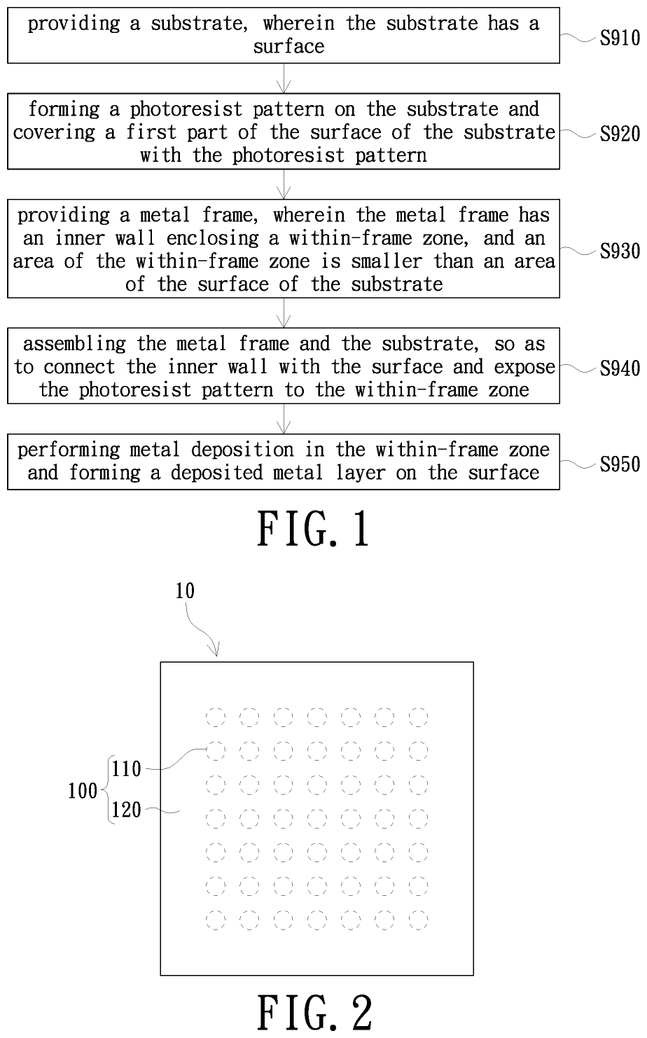

The present invention provides a mask manufacturing method. As shown in FIG. 1, the mask manufacturing method in an embodiment of the present invention includes steps S910 to S950. Further explanation is as follows.

Step S910: providing a substrate, wherein the substrate has a surface. Step S920: forming a photoresist pattern on the substrate and covering a first part of the surface with the photoresist pattern. Please also refer to FIG. 2. The surface 100 of the substrate 10 in this embodiment may include a first part 110. In addition, the surface 100 may further include a second part 120. The first part 110 and the second part 120 can be pre-planned virtual areas for electronic components. For example, the first part 110 and the second part 120 may be planed for objects such as circuit patterns, pixel structures, etc. The material of the substrate 10 may be, for example, nickel, copper, cobalt, titanium, chromium or alloys thereof, such as nickel-iron alloy, stainless steel, titanium alloy, and the like.

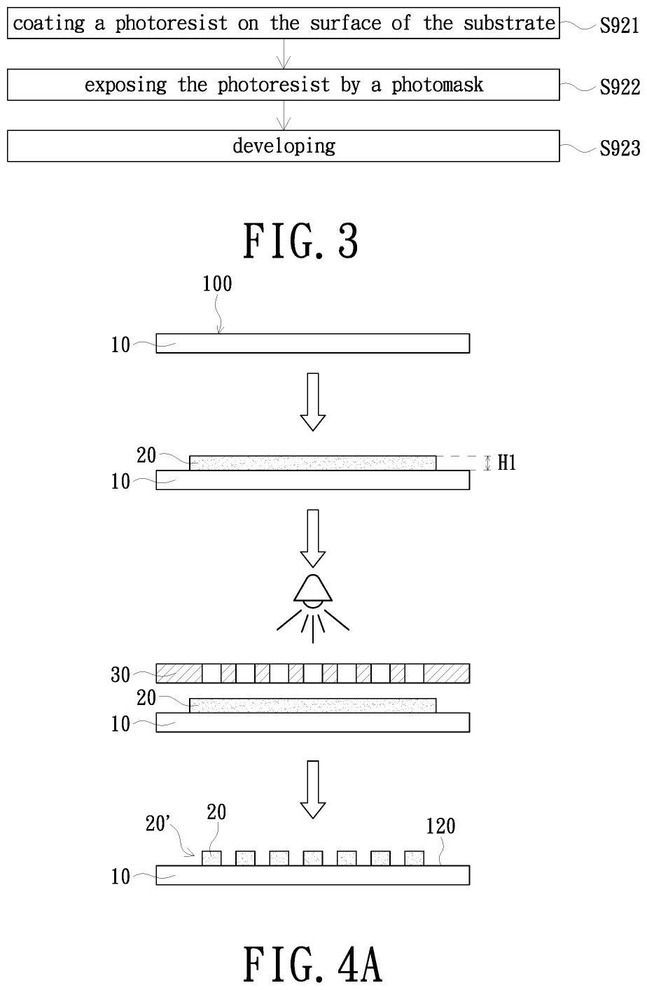

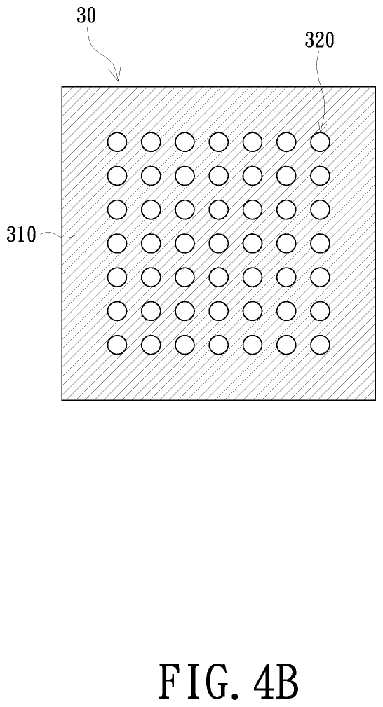

As shown in FIG. 3, step S920 further includes steps S921 to S923. Step S921: coating a photoresist on the surface of the substrate. Step S922: exposing the photoresist by a photomask. Step S923: developing. In step S921, a positive photoresist or a negative photoresist can be used, but the used photoresist is preferably matched with the photomask in step S922. Specifically, the photoresist coating and exposure can be performed in the current manner, or can be achieved by any reasonable means. Step S921 further includes a step of: making the coated photoresist have a height relative to the surface 100 of the substrate 10. In this embodiment as shown in FIG. 4A, the photoresist 20 has a first height H1 relative to the surface 100, wherein the first height H1 is preferably greater than 50 μm.

The photomask 30 used in this embodiment is, for example, a chrome film glass plate. As shown in FIG. 4B, the photomask 30 has a light-shielding pattern 310 and a light-transmitting pattern 320. The light-shielding pattern 310 is composed of, for example, a chromium film, and the portion other than the light-shielding pattern 310 on the chromium film glass plate can constitute the light-transmitting pattern 320. That is, the circular hole array constitutes the light-transmitting pattern 320 in the embodiment of FIG. 4B. For example, it is suitable to use a negative photoresist in step S921 when the light-transmitting pattern 320 of the photomask 30 is the same as the pattern formed by the first part 110 on the substrate 10. On the contrary, it is suitable to use a positive photoresist when the light-shielding pattern 310 is the same as the pattern (not shown in the figure) formed by the first part 110 on the substrate 10.

Taking a negative photoresist as an example. As shown in FIG. 4A, after the developing in step S923, the photoresist 20 that has been irradiated remains on the substrate 10 and forms a photoresist pattern 20′. In step S923, the photoresist that has not been irradiated due to the shielding of the light-shielding pattern 310 is removed, so that the second part 120 of the surface 100 is revealed. In this embodiment as shown in FIGS. 2 and 4A, the first part 110 of the surface 100 of the substrate 10 has a circular hole array pattern, the second part 120 has a mesh-like pattern, and the photoresist pattern 20′ is an array of photoresist blocks, including a plurality of photoresist blocks that are substantially solid cylinders. The mesh of the mesh-like pattern may have, for example, an aperture of 200 μm or less, and the photoresist block of the photoresist pattern 20′ has a diameter of 200 μm or less. In some embodiments of the present invention, the width of the narrowest part of the photoresist pattern 20′ may be, for example, 40 μm, 20 μm or 5 μm. Taking a solid cylindrical photoresist block as an example, the photoresist block can have a minimum diameter of, for example, 40 μm, 20 μm or 5 μm. In other embodiments, the photoresist pattern 20′ may include photoresist blocks of different shapes, such as line-shaped photoresist blocks or photoresist blocks of other geometric shapes. For example, the line-shaped photoresist block may have a width of 40 μm or less when the line-shaped photoresist block is the narrowest part of the formed photoresist pattern 20′.

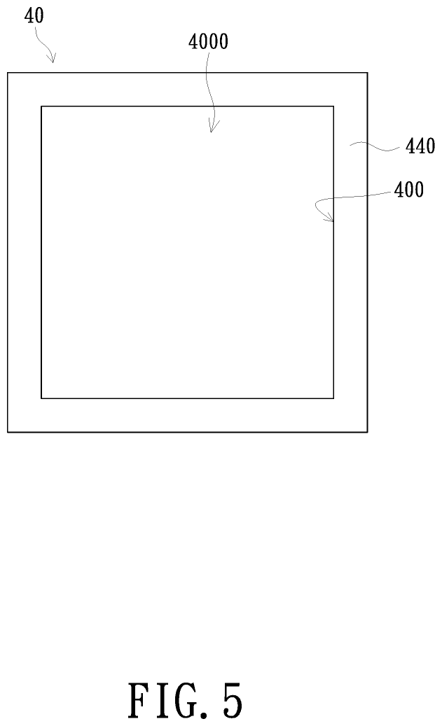

Step S930: providing a metal frame, wherein the metal frame has an inner wall enclosing a within-frame zone, and the area of the within-frame zone is less than the area of the surface of the substrate. Please also refer to FIG. 5, in this embodiment, the within-frame zone 4000 surrounded by the inner wall 400 of the metal frame 40 is similar in shape to the surface 100 of the substrate 10, for example, the within-frame zone 4000 and the surface 100 are two similar rectangles, but is not limited thereto. For example, the metal frame 40 or the within-frame zone 4000 may be circular and are used to prepare a circular mask. The material of the metal frame 40 may be, for example, nickel, copper, cobalt, titanium, chromium or alloys thereof, such as nickel-iron alloy, stainless steel, titanium alloy, and the like. In addition, the material of the metal frame 40 is preferably different from that of the substrate 10.

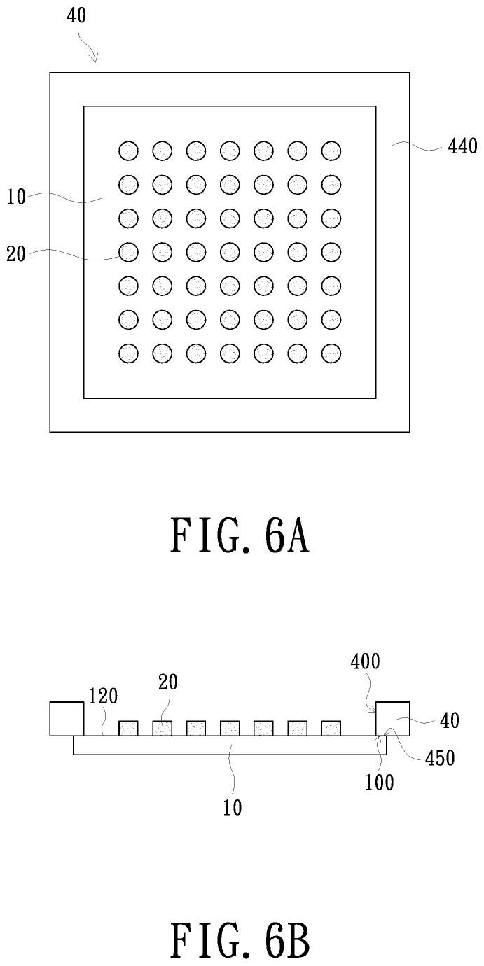

Step S940: assembling the metal frame and the substrate, so as to connect the inner wall with the surface and expose the photoresist pattern to the within-frame zone. Please refer to FIGS. 6A and 6B together. In this embodiment, the metal frame 40 further has a bottom 450, and step S940 further includes a step of: abutting the bottom 450 of the metal frame 40 against the surface 100 of the substrate 10. Specifically, the bottom 450 of the metal frame 40 abuts against the surface 100 of the substrate 10 along the inner wall 400, so as to achieve a close connection between the inner wall 400 of the metal frame 40 and the substrate 10.

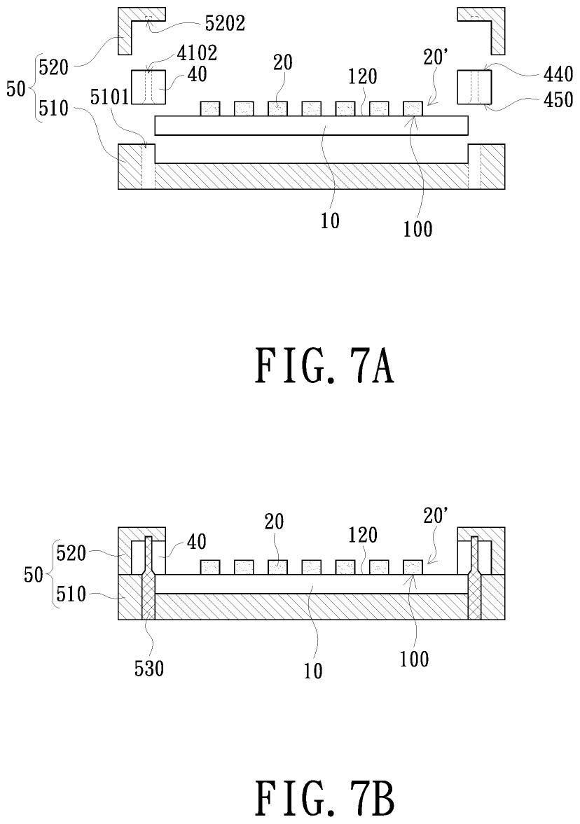

Step S940 may further include, for example, a step of: using equipment to assembly the metal frame 40 and the substrate 10. As shown in FIGS. 7A to 7B, the equipment 50 of this embodiment has a detachable structure and includes, for example, a supporting base 510 and a fixing member 520. The supporting base 510 is suitable for placing the substrate 10 and the metal frame 40. The fixing member 520 is matched with the supporting base 510 and is suitable for arranging the metal frame 40 at an appropriate position relative to the substrate 10. The fixing member 520 may be assembled with the supporting base 510 to further limit and fix the substrate 10 and the metal frame 40 in the equipment 50, but the invention is not limited thereto. The aforementioned assembly and fixation can be achieved by any reasonable means.

The fixing member 520 of this embodiment has an inverted L-shaped cross-sectional shape and can abut against the top 440 and the outside of the metal frame 40. The bottom of the fixing member 520 can abut against the supporting base 510. In addition, the fixing member 520 may have a one-piece structure or a multi-piece stricture. For example, the fixing member 520 may be a one-piece frame structure and is sleeved on the metal frame 40 to fix the metal frame 40 to the substrate 10. Or, as shown in FIG. 7A, at least two fixing members 520 are arranged on opposite sides of the metal frame 40 to fix, for example, the metal frame 40 to the substrate 10. In a preferred embodiment of the present invention, the equipment 50 further has a positioning structure, so that the metal frame 40 is arranged at an appropriate position relative to the substrate 10. The positioning structure of the equipment 50 can be achieved by any reasonable means.

For example, the supporting base 510 and the fixing member 520 are further respectively provided with a positioning hole 5101 and a positioning hole 5202; and the metal frame 40 is provided with a positioning hole 4102. When the metal frame 40 and the substrate 10 are assembled with each other, the positioning holes 5101, 5202 and 4102 are aligned with each other to ensure a proper relative position between the metal frame 40 and the substrate 10. In addition, the positioning holes 5101, 5202 and 4102 are used as locking holes (e.g., screw locking holes), and correspondingly the equipment 50 may include a locking member 530 (e.g., screw) to cooperate with the positioning holes 5101, 5202 and 4102 to realize the assembly of the equipment 50 and the fixing of the metal frame 40 and the substrate 10.

Step S950: performing metal deposition in the within-frame zone and forming a deposited metal layer on the surface. The metal deposition can be achieved by any reasonable means. The deposited metal layer in the embodiment of the present invention is preferably formed by electroforming and electroless plating, and the formed deposited metal layer may be a pure metal layer or an alloy layer. The affinity between the metal used for deposition and the metal frame 40 and the affinity with the substrate 10 are different. Preferably, the affinity between the metal used for deposition and the metal frame 40 is greater than the affinity with the substrate 10.

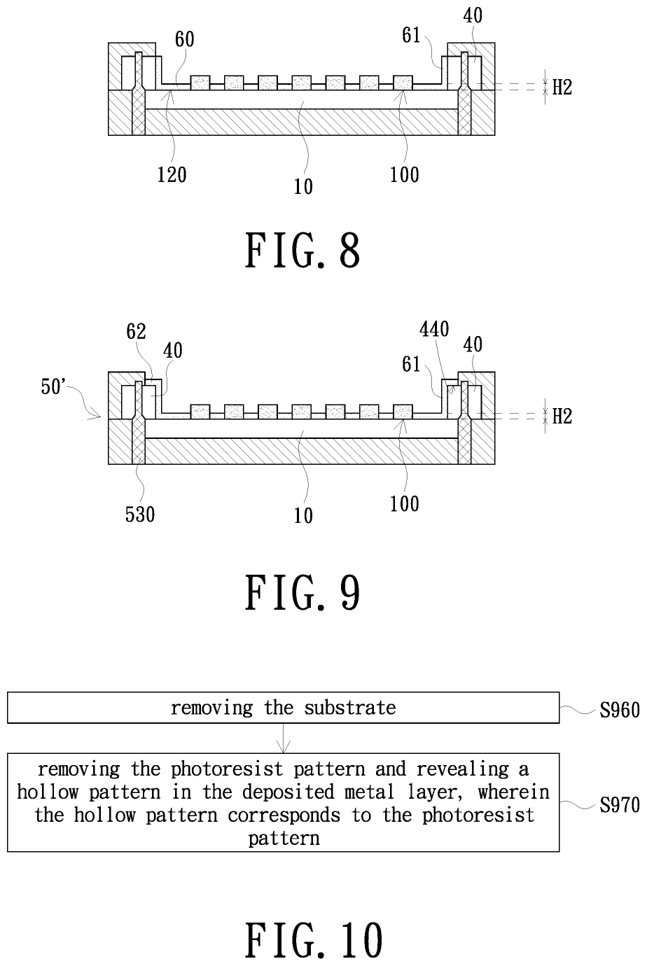

In step S950, the metal is deposited on the exposed second part 120 of the substrate 10, as shown in FIG. 8. In addition, step S950 further includes a step of: making the deposited metal layer 60 have an appropriate thickness and a second height H2 relative to the surface 100, wherein the second height H2 is less than the first height H1. The aforementioned appropriate thickness can be achieved by any reasonable means. For example, the metal deposition in step S950 may be performed at a condition of, for example, 8-10 μm/min to achieve the required thickness. The deposited metal layer 60 in the embodiment of the present invention may have a thickness (i.e., the second height H2) of, for example, 1-50 μm. Since the second part 120 of this embodiment has a mesh-like pattern, the deposited metal layer 60 may correspondingly have a mesh-like pattern.

As shown in FIG. 8, the metal is preferably further deposited on the inner wall 400 of the metal frame 40 and the connection between the inner wall 400 and the substrate 10, so as to form a deposited metal layer 61. In other words, the metal can be deposited on the second part 120 of the surface 100 and the inner wall 400 of the metal frame 40. In addition, the deposited metal layer 61 on the inner wall 400 is integrated with the deposited metal layer 60 on the substrate 10 and is connected to the metal frame 40. In other embodiments of the present invention, the metal can also be deposited on the top 440 of the metal frame 40. For example, in step S950, the top 440 can be exposed through, for example, the cooperation of the equipment 50′ and the metal frame 40 and the deposited metal layer 62 can be formed on the exposed top 440, as shown in FIG. 9.

As shown in FIG. 10, the mask manufacturing method according to an embodiment of the present invention further includes steps S960 to S970. Step S960: removing the substrate. Step S970: removing the photoresist pattern and revealing a hollow pattern in the deposited metal layer, wherein the hollow pattern corresponds to the photoresist pattern. This embodiment does not limit the sequence of steps S960 and S970. Step S960 may further include, for example, a step of: disassembling the equipment 50 to release the metal frame 40 and the substrate 10.

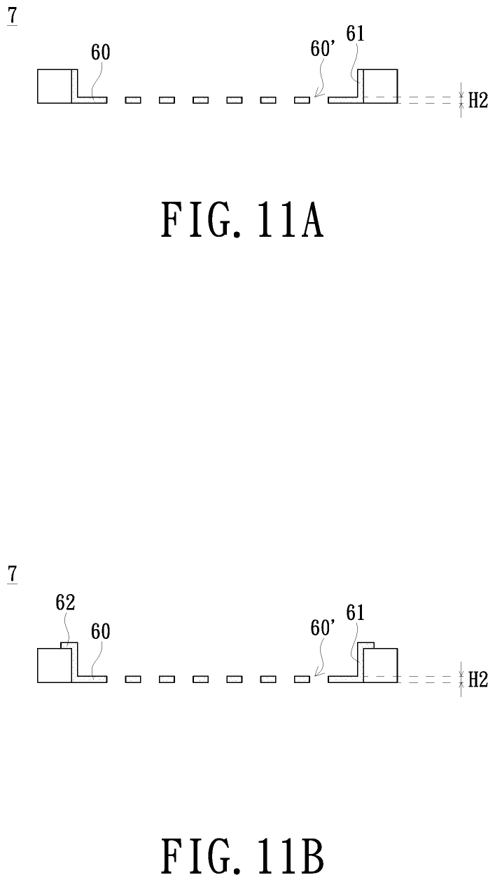

In addition, removing the substrate 10 in step S960 includes a step of: removing the equipment 50/50′. Because the deposited metal layers 60 and 61 are connected to the metal frame 40, the mask 7 (shown in FIG. 11A) composed of the metal frame 40 and the deposited metal layers 60 and 61 can be obtained from steps S960 to S970. In other embodiments, the mask 7 (shown in FIG. 11B) obtained from steps S960 to S970 may be composed of the metal frame 40 and the deposited metal layers 60, 61 and 62. As shown in FIGS. 11A to 11B, the hollow pattern 60′ in the deposited metal layer 60 corresponds to the photoresist pattern 20′ and is a circular hole array pattern. The holes in the circular hole array may have an aperture of 200 μm or less. In some embodiments of the present invention, the width of the narrowest part of the hollow pattern 60′ may be, for example, 40 μm, 20 μm, or 5 μm. Taking the circular hole array pattern as an example, the minimum circular hole may have an aperture of, for example, 40 μm, 20 μm, or 5 μm. In other embodiments, the hollow pattern 60′ may include holes of different shapes, such as linear holes and holes of other geometric shapes. For example, when the linear hole is the narrowest part of the formed hollow pattern 60′, the linear hole may have an aperture of 40 μm or less.

In one aspect, the mask manufactured by the mask manufacturing method of the present invention can prevent the mask pattern (e.g., hollow pattern 60′) from deviating from the original design, so that the hollow pattern 60′ has a higher consistency with the pattern of the first part 110 to avoid the distortion of the mask pattern. Furthermore, the mask (e.g., mask 7) manufactured by the mask manufacturing method of the present invention may have a finer hollow pattern 60′, and correspondingly the pattern of the deposited metal layer 60 may be finer, thereby helping to realize the manufacture of small or precise components. For example, the circular holes of the hollow pattern 60′ may have a smaller aperture, and the density of the circular holes may be higher.

Furthermore, the accuracy of the mask manufactured by the mask manufacturing method of the present invention can be an error of no more than 2 μm. Taking the mask 7 as an example, even if the sections of the first part 110 or the portions of the photoresist pattern 20′ have a small width (e.g., diameter of 5 μm), the formed aperture can be in the range of 3-7 μm.

The present invention further provides a mask manufactured by the aforementioned mask manufacturing method. As shown in FIGS. 11A to 11B, the mask 7 of the embodiment of the present invention has a hollow pattern 60′, wherein the hollow pattern 60′ preferably has a thickness of 1-50 μm. The aperture of the hollow pattern 60′ may be less than 200 μm. The mask of the present invention can be used in processes such as sputtering, evaporation, printing, etc., and realizes the manufacture of small or precise components.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A mask manufacturing method, comprising steps of:
providing a substrate, wherein the substrate has a surface;
forming a photoresist pattern on the substrate and covering a first part of the surface of the substrate with the photoresist pattern;
providing a metal frame, wherein the metal frame has an inner wall enclosing a within-frame zone, and an area of the within-frame zone is smaller than an area of the surface of the substrate;
assembling the metal frame and the substrate, so as to connect the inner wall with the surface and expose the photoresist pattern to the within-frame zone; and
performing metal deposition in the within-frame zone and forming a deposited metal layer on the surface.

2. The mask manufacturing method according to claim 1, wherein the step of forming the photoresist pattern on the substrate further comprises steps of:
coating a photoresist on the surface of the substrate;
exposing the photoresist by a photomask; and
developing.

3. The mask manufacturing method according to claim 1, wherein the step of forming the photoresist pattern on the substrate further comprises a step of:
forming a second part on the surface, wherein the second part is exposed to the surface.

4. The mask manufacturing method according to claim 1, wherein the metal frame further has a bottom, and the step of assembling the metal frame and the substrate further comprises a step of:
abutting the bottom of the metal frame against the surface of the substrate.

5. The mask manufacturing method according to claim 1, wherein the step of assembling the metal frame and the substrate further comprises a step of:
using equipment to fix the metal frame on the substrate.

6. The mask manufacturing method according to claim 3, wherein the step of performing metal deposition in the within-frame zone further comprises a step of:
depositing at least one metal on the second part of the surface and the inner wall of the metal frame.

7. The mask manufacturing method according to claim 6, wherein the metal frame further has a top, and the step of performing metal deposition in the within-frame zone further comprises a step of:
depositing the at least one metal on the top.

8. The mask manufacturing method according to claim 6, wherein the step of performing metal deposition in the within-frame zone further comprises a step of:
integrally forming the deposited metal layer along the second part of the surface and the inner wall of the metal frame, and connecting the deposited metal layer to the metal frame.

9. The mask manufacturing method according to claim 1, further comprising steps of:
removing the substrate; and
removing the photoresist pattern and revealing a hollow pattern in the deposited metal layer, wherein the hollow pattern corresponds to the photoresist pattern.

10. The mask manufacturing method according to claim 9, wherein the hollow pattern has an aperture, and the aperture is less than 200 μm.

11. The mask manufacturing method according to claim 10, wherein the aperture is 3-7 μm, the aperture corresponds to a part of the photoresist pattern, and the part of the photoresist pattern has a width of 5 μm.

12. The mask manufacturing method according to claim 1, wherein the photoresist pattern has a first height on the surface, the deposited metal layer has a second height on the surface, and the second height is less than the first height.

13. A mask manufactured by a mask manufacturing method, the mask manufacturing method comprising steps of:
providing a substrate, wherein the substrate has a surface;
forming a photoresist pattern on the substrate and covering a first part of the surface of the substrate with the photoresist pattern;
providing a metal frame, wherein the metal frame has an inner wall enclosing a within-frame zone, and an area of the within-frame zone is smaller than an area of the surface of the substrate;
assembling the metal frame and the substrate, so as to connect the inner wall with the surface and expose the photoresist pattern to the within-frame zone; and
performing metal deposition in the within-frame zone and forming a deposited metal layer on the surface.

14. The mask according to claim 13, wherein the step of forming the photoresist pattern on the substrate further comprises steps of:
coating a photoresist on the surface of the substrate;
exposing the photoresist by a photomask; and
developing.

15. The mask according to claim 13, wherein the step of forming the photoresist pattern on the substrate further comprises a step of:
forming a second part on the surface, wherein the second part is exposed to the surface.

16. The mask according to claim 13, wherein the metal frame further has a bottom, and the step of assembling the metal frame and the substrate further comprises a step of:
abutting the bottom of the metal frame against the surface of the substrate.

17. The mask according to claim 13, wherein the step of assembling the metal frame and the substrate further comprises a step of:
using equipment to fix the metal frame on the substrate.

18. The mask according to claim 13, wherein the mask manufacturing method further comprises steps of:
removing the substrate; and
removing the photoresist pattern and revealing a hollow pattern in the deposited metal layer, wherein the hollow pattern corresponds to the photoresist pattern.

19. The mask according to claim 13, wherein the photoresist pattern has a first height on the surface, the deposited metal layer has a second height on the surface, and the second height is less than the first height.

20. The mask according to claim 13, wherein the deposited metal layer has a thickness of 1-50 μm.
